(19) United States
(12) Patent Application Publication
(10) Pub. No.: US 2016/0260854 A1
(43) Pub. Date: Sep. 8, 2016

(54) SOLAR CELL MODULE AND METHOD OF MANUFACTURING THE SAME

(71) Applicant: LG ELECTRONICS INC., Seoul (KR)

(72) Inventor: Sungeun LEE, Seoul (KR)

(73) Assignee: LG ELECTRONICS INC., Seoul (KR)

(21) Appl. No.: 15/155,600

(22) Filed: May 16, 2016

Related U.S. Application Data
(62) Division of application No. 12/887,008, filed on Sep. 21, 2010.

(30) Foreign Application Priority Data
Sep. 28, 2009 (KR) 10-2009-0091621

(51) Int. Cl. H01L 31/0224; H01L 31/0236; H01L 31/049; H01L 31/18; H01L 31/05; H01L 31/048

(52) U.S. Cl. CPC H01L 31/022441; H01L 31/0504; H01L 31/0481; H01L 31/049; H01L 31/18; H01L 31/02366

(57) ABSTRACT

A method of manufacturing a solar cell module can include positioning an upper protective layer on a transparent member; positioning a plurality of solar cells on the upper protective layer at constant intervals; positioning an interconnector in a space between adjacent solar cells of the plurality of solar cells, the interconnector including holes formed in connection portions between the interconnector and electrode parts of the adjacent solar cells; injecting a liquefied solder through the holes to solder the interconnector to the adjacent solar cells; positioning a lower protective layer on the plurality of solar cells; and attaching the upper protective layer to the lower protective layer.

### CROSS-REFERENCE TO RELATED APPLICATIONS

This application is a Divisional of co-pending U.S. patent application Ser. No. 12/887,008 filed on Sep. 21, 2010, which claims the benefit under 35 U.S.C. §119(a) to Korean Patent Application No. 10-2009-0091621 filed on Sep. 28, 2009, all of which are hereby expressly incorporated by reference into the present application.

### BACKGROUND OF THE INVENTION

1. Field of the Invention

Example embodiments of the invention relate to a solar cell module and a method of manufacturing the same.

2. Description of the Related Art

Recently, as existing energy sources such as petroleum and coal are expected to be depleted, interests in renewable energy for replacing the existing energy sources are increasing. As the renewable energy, solar cells for generating electric energy from solar energy have been particularly spotlighted. A back contact solar cell capable of increasing the size of a light receiving area by forming both an electron electrode and a hole electrode on a back surface of a substrate (i.e., the surface of the substrate on which light is not incident) has been recently developed. Hence, the efficiency of the back contact solar cell is improved.

A solar cell module manufactured by connecting the plurality of back contact solar cells each having the above-described structure in series or in parallel to one another is used to obtain a desired output. The solar cell module is a moisture-proof module manufactured in a panel form.

### SUMMARY OF THE INVENTION

In one aspect, there is a solar cell module including a plurality of solar cells, an interconnector configured to electrically connect adjacent solar cells of the plurality of solar cells to one another, the interconnector including holes in connection portions between the interconnector and electrode parts of the adjacent solar cells, at least one protective layer configured to protect the plurality of solar cells, a transparent member positioned on light receiving surfaces of the plurality of solar cells, and a back sheet positioned opposite the light receiving surfaces of the plurality of solar cells.

Each of the plurality of solar cells includes a substrate, and an electron electrode and a hole electrode positioned on a back surface of the substrate.

The solar cell module may further include a shield for maintaining a distance between the adjacent back contact solar cells. The shield may be formed of a polyester tape having an adhesive. The at least one protective layer includes an upper protective layer and a lower protective layer. In this instance, the upper protective layer and the lower protective layer may be formed of the same material, for example, ethylene vinyl acetate (EVA) of a film form.

The upper protective layer and the lower protective layer may be formed of different materials. For example, the lower protective layer may be formed of cured siloxane, for example, cured poly dialkyl siloxane, or include poly dialkyl siloxane, and the upper protective layer may be formed of ethylene vinyl acetate (EVA) of a film form.

After a liquid siloxane precursor is applied to the plurality of back contact solar cells, a portion of the applied siloxane precursor is filled in a space between the back contact solar cells because of the fluidity properties of the liquid siloxane precursor and is cured through a thermal process. Hence, the cured siloxane is attached to the upper protective layer.

A front surface of the interconnector may be processed to have the same color as the back contact solar cell or the back sheet, for example, black or white, so as to prevent a metal color of the interconnector from being observed through a light receiving surface of the solar cell module.

The interconnector may further include a slit, and the slit may be positioned on the shield.

In another aspect, there is a method of manufacturing a solar cell module including positioning an upper protective layer on a transparent member, positioning a plurality of solar cells on the upper protective layer at constant intervals, positioning an interconnector in a space between adjacent solar cells of the plurality of solar cells, the interconnector including holes formed in connection portions between the interconnector and electrode parts of the adjacent solar cells, injecting a liquefied solder through the holes to solder the interconnector to the adjacent solar cells, positioning a lower protective layer on the plurality of solar cells, and attaching the upper protective layer to the lower protective layer.

The positioning of the plurality of back contact solar cells on the upper protective layer at constant intervals may include using a shield formed of an adhesive tape. In this instance, the upper protective layer and the lower protective layer may be formed of ethylene vinyl acetate (EVA) of a film form.

The positioning of the lower protective layer may include applying a liquid siloxane precursor to the plurality of back contact solar cells to fill a space between adjacent back contact solar cells with a portion of the applied liquid siloxane precursor. The attaching of the upper protective layer to the lower protective layer may include performing a curing process using a thermal processing to attach the liquid siloxane precursor to the upper protective layer and curing the liquid siloxane precursor.

The thermal processing may be performed in a state where a back sheet is positioned on the liquid siloxane precursor.

The thermal processing may be performed at a temperature of 200° C. to 400° C. The liquid siloxane precursor may contain poly dialkyl siloxane. The upper protective layer may be formed of ethylene vinyl acetate (EVA) of a film form.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIG. 1 is a plane view of a solar cell module according to an example embodiment of the invention;

FIG. 2 is a plane view of an interconnector shown in FIG. 1;

FIG. 3 is a partial cross-sectional view of the solar cell module shown in FIG. 1;

FIG. 4 is a partial cross-sectional view of a back contact solar cell shown in FIG. 1;

FIG. 5 is a block diagram sequentially illustrating a method of manufacturing the solar cell module shown in FIG. 1;

FIG. 6 is a plane view of a solar cell module according to another example embodiment of the invention;

FIG. 7 is a partial cross-sectional view of the solar cell module shown in FIG. 6; and

FIG. 8 is a block diagram sequentially illustrating a method of manufacturing the solar cell module shown in FIG. 6.

### DETAILED DESCRIPTION OF THE EMBODIMENTS

The invention will be described more fully hereinafter with reference to the accompanying drawings, in which example embodiments of the inventions are shown. This invention may, however, be embodied in many different forms and should not be construed as limited to the embodiments set forth herein.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, it will be understood that when an element such as a layer, film, region, or substrate is referred to as being “entirely” on another element, it may be on the entire surface of the other element and may not be on a portion of an edge of the other element.

Reference will now be made in detail to embodiments of the invention, examples of which are illustrated in the accompanying drawings.

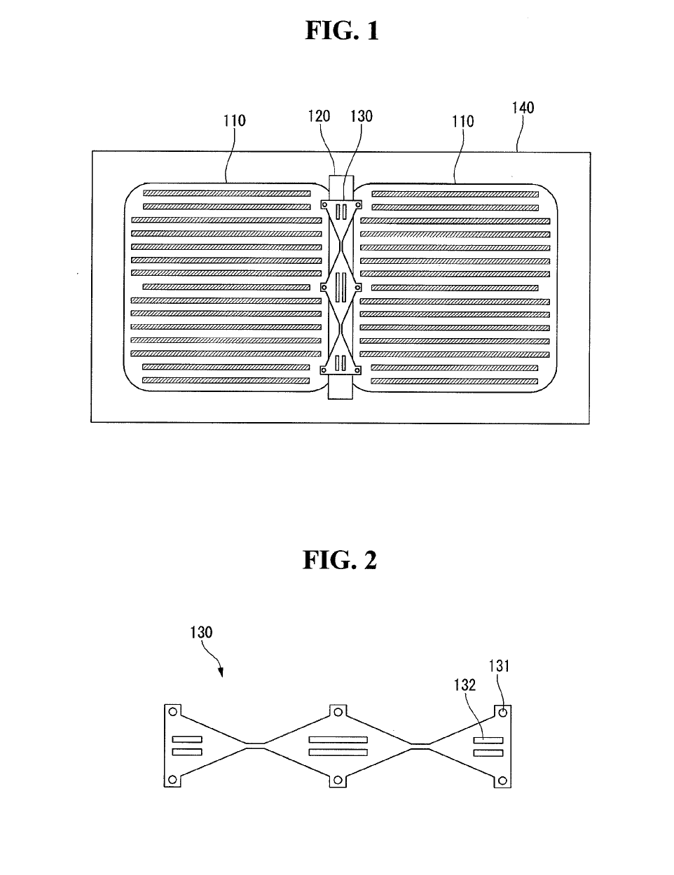

A solar cell module according to an example embodiment of the invention is described in detail with reference to FIGS. 1 to 4.

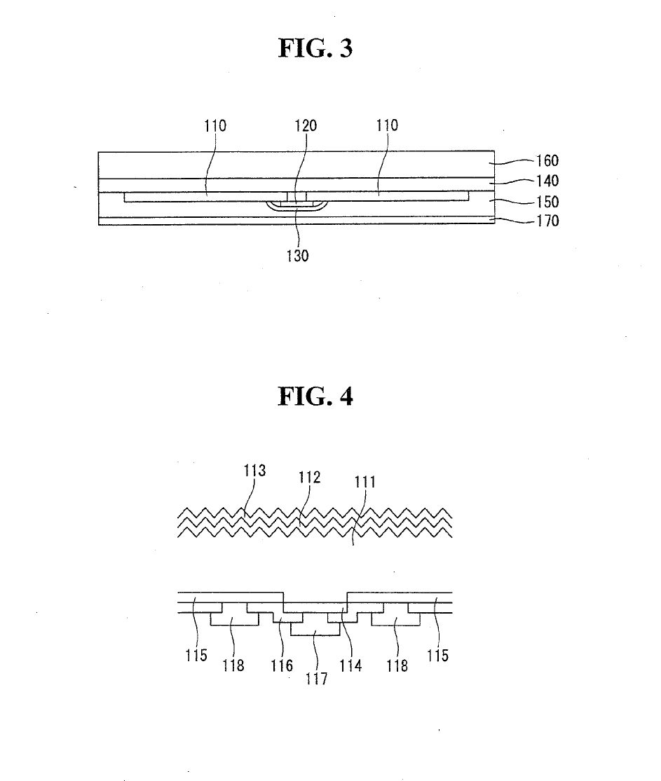

FIG. 1 is a plane view of a solar cell module according to an example embodiment of the invention. In FIG. 1, a back sheet is shown as removed in order to show the details of the solar cell module. FIG. 2 is a plane view of an interconnector shown in FIG. 1. FIG. 3 is a partial cross-sectional view of the solar cell module shown in FIG. 1. FIG. 4 is a partial cross-sectional view of a back contact solar cell shown in FIG. 1.

As shown in FIGS. 1 to 4, a solar cell module according to an example embodiment of the invention includes a plurality of back contact solar cells 110 (also referred to as back junction solar cells), a shield 120 that is positioned on back surfaces of the back contact solar cells 110 and maintains a distance between the back contact solar cells 110 constant, an interconnector 130 that is positioned on a back surface of the shield 120 and electrically connects the adjacent back contact solar cells 110 to one another, upper and lower protective layers 140 and 150 for protecting the back contact solar cells 110, a transparent member 160 that is positioned on the upper protective layer 140 on light receiving surfaces of the back contact solar cells 110, and a back sheet 170 that is positioned under the lower protective layer 150 on surfaces opposite the light receiving surfaces of the back contact solar cells 110.

Although FIG. 1 shows only the two back contact solar cells 110, the number of back contact solar cells 110 is not limited to that shown in the example embodiment of the invention.

The back sheet 170 prevents moisture or oxygen from penetrating into a back surface of the solar cell module, thereby protecting the back contact solar cells 110 from an external environment. The back sheet 170 may have a multi-layered structure including a moisture/oxygen penetrating prevention layer, a chemical corrosion prevention layer, a layer having insulating characteristics, etc.

The upper protective layer 140 is attached to the lower protective layer 150 in a state where the upper protective layer 140 is positioned on the back contact solar cells 110. Hence, the upper and lower protective layers 140 and 150 and the back contact solar cells 110 form an integral body. The upper and lower protective layers 140 and 150 prevent corrosion of the back contact solar cells 110 resulting from the moisture penetration and protect the back contact solar cells 110 from an impact. The upper and lower protective layers 140 and 150 may be formed of the same material, for example, ethylene vinyl acetate (EVA) manufactured in a film form. Other materials may be used.

The transparent member 160 on the upper protective layer 140 is formed of a tempered glass having a high transmittance and excellent damage prevention characteristic. The tempered glass may be a low iron tempered glass containing a small amount of iron. The transparent member 160 may have an embossed inner surface so as to increase a scattering effect of light.

The interconnector 130 is formed of a conductive metal and is soldered to electrode parts, for example, tabbing metal electrodes formed on the back surfaces of the back contact solar cells 110 to electrically connect the adjacent back contact solar cells 110 to one another. The interconnector 130 has holes 131 for exposing a portion of the back surface of each back contact solar cell 110 in connection portions between the interconnector 130 and the tabbing metal electrodes formed on the back surfaces of the back contact solar cells 110, so that the interconnector 130 and the back contact solar cells 110 can be automatically attached to each other by a liquefied solder, for example, a solder paste injected through the holes 131.

The holes 131 are used to perform an automatic attaching process using the liquefied solder. The adjacent back contact solar cells 110 and the interconnector 130 are soldered to each other by injecting the liquefied solder through the holes 131 using a dispenser or a direct printing equipment and then performing the curing process. Thus, an electrical connection between the adjacent back contact solar cells 110 through the interconnector 130 is completed along with the soldering process.

In the embodiment of the invention, the liquefied solder (i.e., the solder paste) indicates lead of a semisolid state, for example. The curing process of the liquefied solder may be performed using a heating device such as an oven. A solder cream may be previously applied to the back surface of the back contact solar cell 110 to form the holes 131 for the soldering process.

The shield 120 is positioned on the back surfaces of the adjacent back contact solar cells 110 so as to provide distance maintenance and an electrical insulation between the adjacent back contact solar cells 110. The shield 120 is formed of a polyester tape having an adhesive and is attached to ends of the adjacent back contact solar cells 110. The shield 120 prevents a short-circuit generated because the liquefied solder injected through the holes 131 for attaching the interconnector 130 to the back contact solar cells 110 is diffused between the back contact solar cells 110. Further, the shield 120 prevents the interconnector 130 from being viewed in front of the solar cell module through a space between the adjacent back contact solar cells 110.

The interconnector 130 is attached to the shield 120 and is soldered to the tabbing metal electrodes in a formation portion of the holes 131 using the liquefied solder. The interconnector 130 has slits 132 for reducing strains resulting from an expansion or a contraction of the interconnector 130 generated by heat or lack thereof. The slits 132 are positioned on the shield 120. Portions of the interconnector 130 may have a trapezoidal shape or a triangular shape, but are not limited thereto.

Although FIG. 1 illustrates the electrical connection between the adjacent back contact solar cells 110 through the one interconnector 130, the plurality of back contact solar cells 110 may be electrically connected using a plurality of interconnectors 130.

For example, the adjacent back contact solar cells 110 may be electrically connected to one another using three interconnectors 130, each of which has the holes 131 at both ends thereof.

The size and the number of the holes 131 included in the interconnector 130 may be adjusted depending on the size of the back contact solar cells 110. The size or diameters of the holes may be 100 μm to 500 μm, preferably, but not necessarily, 200 μm to 300 μm. The number of the holes may be 3 to 15, preferably, but not necessarily, 6 to 10 depending on the number of the tabbing metal electrodes. But the embodiments of the invention are not limited thereto.

As shown in FIG. 4, the back contact solar cell 110 used in the solar cell module includes a semiconductor substrate 111 of a first conductive type, a front surface field (FSF) layer 112 formed at one surface (for example, a light receiving surface) of the semiconductor substrate 111, an anti-reflection layer 113 formed on the FSF layer 112, a first doped region 114 that is formed at another surface of the semiconductor substrate 111 and is heavily doped with first conductive type impurities, a second doped region 115 that is formed at the another surface of the semiconductor substrate 111 at a location adjacent to the first doped region 114 and is heavily doped with second conductive type impurities opposite the first conductive type impurities, a back passivation layer 116 exposing a portion of each of the first doped region 114 and the second doped region 115, a hole electrode 117 (hereinafter referred to as “a first electrode”) electrically connected to the exposed portion of the first doped region 114, and an electron electrode 118 (hereinafter referred to as “a second electrode”) electrically connected to the exposed portion of the second doped region 115.

The light receiving surface of the semiconductor substrate 111 is textured to form a textured surface corresponding to an uneven surface having a plurality of uneven portions. In this instance, each of the FSF layer 112 and the anti-reflection layer 113 has a textured surface.

The semiconductor substrate 111 is formed of single crystal silicon of the first conductive type, for example, n-type, though not required. Alternatively, the semiconductor substrate 111 may be of a p-type and/or may be formed of polycrystalline silicon. Further, the semiconductor substrate 111 may be formed of other semiconductor materials other than silicon.

Because the light receiving surface of the semiconductor substrate 111 is the textured surface, an absorptance of light increases. Hence, the efficiency of the back contact solar cell 110 is improved.

The FSF layer 112 formed at the textured surface of the semiconductor substrate 111 is a region that is more heavily doped with, for example, impurities of a group V element such as phosphorus (P), arsenic (As), and antimony (Sb) than the semiconductor substrate 111. The FSF layer 112 performs an operation similar to a back surface field (B S F) layer. Thus, a recombination and/or a disappearance of electrons and holes separated by incident light around the light receiving surface of the semiconductor substrate 111 are prevented or reduced.

The anti-reflection layer 113 on the surface of the FSF layer 112 is formed of silicon nitride (SiNx) and/or silicon dioxide (SiO2), etc. The anti-reflection layer 113 reduces a reflectance of incident light and increases a selectivity of a predetermined wavelength band, thereby increasing the efficiency of the back contact solar cell 110.

The first doped region 114 is a p-type heavily doped region, and the second doped region 115 is a region that is more heavily doped with n-type impurities than the semiconductor substrate 111. Thus, the first doped region 114 and the n-type semiconductor substrate 111 form a p-n junction. The first doped region 114 and the second doped region 115 serve as a moving path of carriers (electrons and holes) and respectively collect holes and electrons.

The back passivation layer 116 exposing a portion of each of the first doped region 114 and the second doped region 115 is formed of silicon nitride (SiNx), silicon dioxide (SiO2), or a combination thereof. The back passivation layer 116 prevents or reduces a recombination and/or a disappearance of electrons and holes separated from carriers and reflects incident light to the inside of the back contact solar cell 110 so that the incident light is not reflected to the outside of the back contact solar cell 110. Namely, the back passivation layer 116 prevents a loss of the incident light and reduces a loss amount of the incident light. The back passivation layer 116 may have a single-layered structure or a multi-layered structure such as a double-layered structure or a triple-layered structure.

The first electrode 117 is formed on the first doped region 114 not covered by the back passivation layer 116 and on a portion of the back passivation layer 116 adjacent to the first doped region 114. The second electrode 118 is formed on the second doped region 115 not covered by the back passivation layer 116 and on a portion of the back passivation layer 116 adjacent to the second doped region 115. Thus, the first electrode 117 is electrically connected to the first doped region 114, and the second electrode 118 is electrically connected to the second doped region 115. The first and second electrodes 117 and 118 are spaced apart from each other at a constant distance and extend parallel to each other in one direction.

As described above, because a portion of each of the first and second electrodes 117 and 118 overlaps a portion of the back passivation layer 116 and is connected to a bus bar area, a contact resistance and a series resistance decrease when the first and second electrodes 117 and 118 contact an external driving circuit, etc. Hence, the efficiency of the back contact solar cell 110 can be improved.

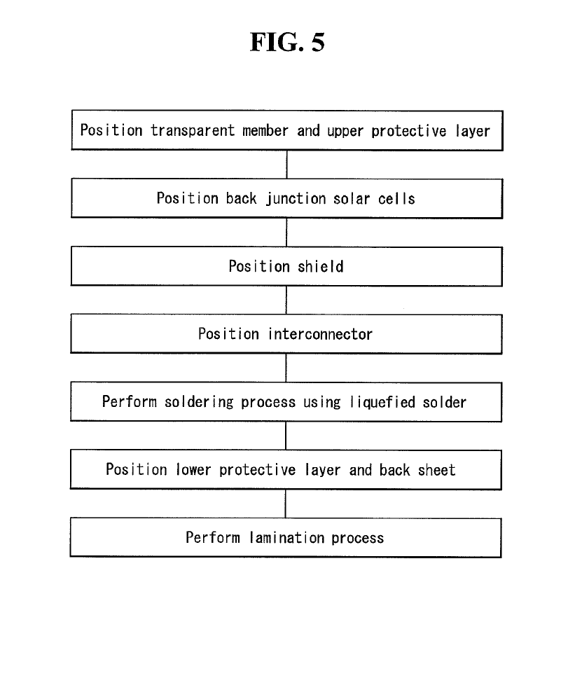

A method of manufacturing the solar cell module according to the example embodiment of the invention is described with reference to FIG. 5.

FIG. 5 is a block diagram sequentially illustrating a method of manufacturing the solar cell module shown in FIG. 1.

As shown in FIGS. 1 to 5, first, the upper protective layer 140 of the film form is positioned on the transparent member 160. As described above, the upper protective layer 140 is formed of ethylene vinyl acetate (EVA).

After the upper protective layer 140 is positioned, the plurality of back contact solar cells 110 is positioned on the upper protective layer 140 at constant intervals. The shield 120 is attached or positioned to the back surfaces of the back contact solar cells 110.

The interconnector 130 is positioned on the shield 120 so that the holes 131 of the interconnector 130 are aligned with the tabbing metal electrodes formed on the back surfaces of the back contact solar cells 110. Subsequently, the liquefied solder is injected through the holes 131 using the application device and then is cured.

When the soldering between the interconnector 130 and the back contact solar cells 110, and the electrical connection between the back contact solar cells 110 are completed through the above-described process, the lower protective layer 150 formed of the same material as the upper protective layer 140 is positioned on the back contact solar cells 110. The back sheet 170 is then positioned on the lower protective layer 150.

Next, a lamination process is performed to form the above components as an integral body. More specifically, the transparent member 160, the upper protective layer 140, the back contact solar cells 110, the lower protective layer 150, and the back sheet 170 are attached to one another through the lamination process to thereby form an integral body.

According to the method of manufacturing the solar cell module, because the interconnector 130 has the holes 131, the electrical connection between the interconnector 130 and the back contact solar cells 110 is completed by the liquefied solder injected through the holes 131 using the application device. Accordingly, the electrical connection between the interconnector 130 and the back contact solar cells 110 may be automatized.

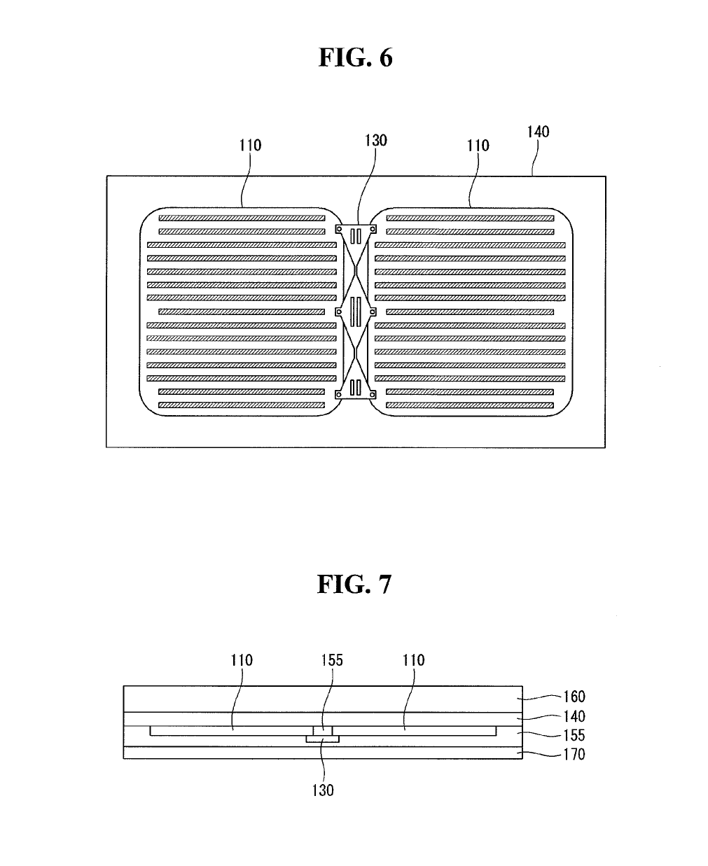

FIG. 6 is a plane view of a solar cell module according to another example embodiment of the invention from which a back sheet is shown as removed in order to show the details of the solar cell module. FIG. 7 is a partial cross-sectional view of the solar cell module shown in FIG. 6.

In the following description, structures and components identical or equivalent to those illustrated in FIGS. 1 and 4 are designated with the same reference numerals, and a further description may be briefly made or may be entirely omitted.

As shown in FIGS. 6 and 7, a solar cell module according to another example embodiment of the invention includes a plurality of back contact solar cells 110 (also referred to as back junction solar cells), an interconnector 130 that is positioned on back surfaces surface of the back contact solar cells 110 and electrically connects the adjacent back contact solar cells 110 to one another, upper and lower protective layers 140 and 155 for protecting the back contact solar cells 110, a transparent member 160 that is positioned on the upper protective layer 140 on light receiving surfaces of the back contact solar cells 110, and a back sheet 170 that is positioned under the lower protective layer 155 on surfaces opposite the light receiving surfaces of the back contact solar cells 110.

In the present embodiment, the upper protective layer 140 and the lower protective layer 155 are formed of different materials. More specifically, the upper protective layer 140 is formed of ethylene vinyl acetate (EVA) manufactured in a film form. The lower protective layer 155 is formed of a cured material obtained by performing thermal processing on a liquid compound, for example, cured siloxane containing poly dialkyl siloxane.

When a liquid siloxane precursor is applied to the back contact solar cells 110, a portion of the applied siloxane precursor is filled in a space between the back contact solar cells 110 because of the siloxane precursor having fluidity properties and is cured through a thermal process.

In the structure of the solar cell module, a reason to form the lower protective layer 155 using the liquid compound is to enable a process for manufacturing the solar cell module to be automatized by removing a shield used in the related art. The reason is described in detail in a method of manufacturing the solar cell module which will be described below.

The interconnector 130 has the same configuration as FIGS. 1 to 4. More specifically, the interconnector 130 has holes 131 formed in a contact portion between the interconnector 130 and tabbing metal electrodes and slits 132 for reducing strains resulting from an expansion or a contraction of the interconnector 130 generated by heat or lack thereof.

The holes 131 are used to perform an automatic attaching process using a liquefied solder. An electrical connection between the adjacent back contact solar cells 110 through the interconnector 130 is completed by applying the liquefied solder to the holes 131 using an application device.

In the present embodiment, the shield 120 (refer to FIG. 1) used in the previous embodiment is not used, and the distance maintenance and the electrical insulation between the adjacent back contact solar cells 110 are achieved by the lower protective layer 155. Hence, when the interconnector 130 is observed through the light receiving surface of the solar cell module, the interconnector 130 may be observed in (or disposed over) a space between the adjacent back contact solar cells 110.

However, the interconnector 130 is formed of a conductive metal of a different color from the back contact solar cells 110. Accordingly, one surface of the interconnector 130 (i.e., the surface of the interconnector 130 towards the light receiving surface of the solar cell module) may be processed or treated with (or to have) the same color as the semiconductor substrate 111 of the back contact solar cell 110 or the back sheet 170, for example, black or white, so as to improve an appearance of the solar cell module.

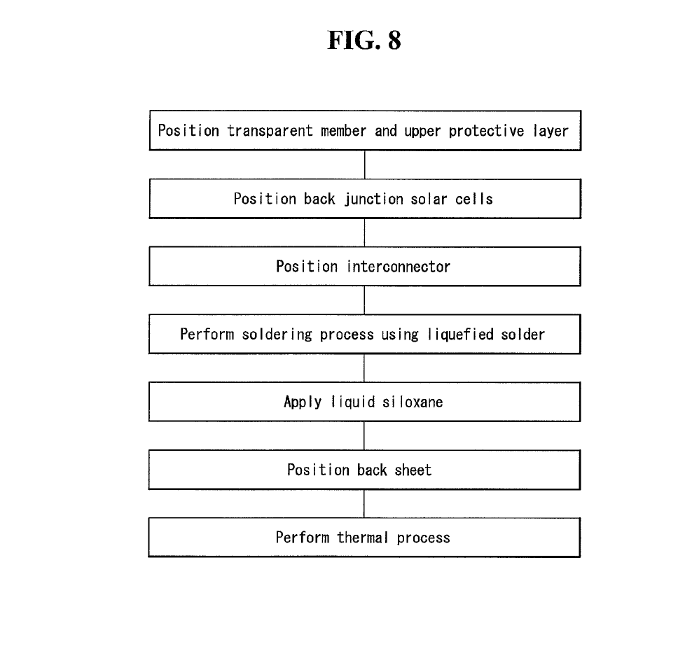

A method of manufacturing the solar cell module according to the example embodiment of the invention is described with reference to FIG. 8.

FIG. 8 is a block diagram sequentially illustrating a method of manufacturing the solar cell module shown in FIG. 6.

As shown in FIGS. 6 to 8, first, the upper protective layer 140 of the film form is positioned on the transparent member 160. As described above, the upper protective layer 140 is formed of ethylene vinyl acetate (EVA).

After the upper protective layer 140 is positioned, the plurality of back contact solar cells 110 is positioned on the upper protective layer 140 at constant intervals. The interconnector 130 is positioned on the back contact solar cells 110 so that the holes 131 of the interconnector 130 are aligned with the tabbing metal electrodes formed on the back surfaces of the back contact solar cells 110. Subsequently, the liquefied solder is injected through the holes 131 using the application device.

When the soldering between the interconnector 130 and the back contact solar cells 110 and the electrical connection between the back contact solar cells 110 are completed through the above-described process, the liquid siloxane precursor, for example, poly dialkyl siloxane, is applied to the back contact solar cells 110 using the application device. The liquid siloxane precursor may be, or include, dimethylsilyl oxy acrylate in other embodiments.

When the liquid siloxane precursor is applied to the back contact solar cells 110, a portion of the applied liquid siloxane precursor is filled in a space between the adjacent back contact solar cells 110. In this instance, an amount of the applied liquid siloxane precursor may be adjusted within the proper range.

Subsequently, the back sheet 170 is positioned on the liquid siloxane precursor, and a thermal process is performed at a temperature of 200° C. to 400° C. to cure the liquid siloxane precursor. When a curing process is performed through the thermal process, the cured siloxane precursor forms the lower protective layer 155. The lower protective layer 155 formed using the siloxane precursor is attached to the upper protective layer 140 of the film form and the back sheet 170.

The attachment between the upper protective layer 140 and the transparent member 160 may be achieved through the thermal process or a separate lamination process. Further, the liquefied solder may be cured through the thermal process for curing the liquid siloxane without performing a separate process for curing the liquefied solder.

In the method of manufacturing the solar cell module according to the present embodiment, the interconnector 130 is attached to the back contact solar cells 110 by the liquefied solder injected through the holes 131 using the application device. Further, the lower protective layer 155 for providing the distance maintenance and the electrical insulation between the adjacent back contact solar cells 110 is formed using the liquid compound applied using the application device. Accordingly, a process for positioning components of the solar cell module and the electrical connection between the interconnector 130 and the back contact solar cells 110 may be automatized.

Although embodiments have been described with reference to a number of illustrative embodiments thereof, it should be understood that numerous other modifications and embodiments can be devised by those skilled in the art that will fall within the scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of manufacturing a solar cell module, the method comprising:
positioning an upper protective layer on a transparent member;
positioning a plurality of solar cells on the upper protective layer at constant intervals;
positioning an interconnector in a space between adjacent solar cells of the plurality of solar cells, the interconnector including holes formed in connection portions between the interconnector and electrode parts of the adjacent solar cells;
injecting a liquefied solder through the holes to solder the interconnector to the adjacent solar cells;
positioning a lower protective layer on the plurality of solar cells; and
attaching the upper protective layer to the lower protective layer.

2. The method of claim 1, wherein the positioning of the plurality of solar cells on the upper protective layer at constant intervals comprises using a shield formed of an adhesive tape.

3. The method of claim 1, wherein the upper protective layer and the lower protective layer are formed of ethylene vinyl acetate (EVA) of a film form.

4. The method of claim 1, wherein the positioning of the lower protective layer comprises applying a liquid siloxane precursor to the plurality of solar cells to fill a space between the adjacent solar cells with a portion of the applied liquid siloxane precursor, and
the attaching of the upper protective layer to the lower protective layer comprises performing a curing process using a thermal processing to attach the liquid siloxane precursor to the upper protective layer and to cure the liquid siloxane precursor.

5. The method of claim 4, wherein the thermal processing is performed in a state where a back sheet is positioned on the liquid siloxane precursor.

6. The method of claim 4, wherein the thermal processing is performed at a temperature of 200° C. to 400° C.

7. The method of claim 4, wherein the liquid siloxane precursor contains poly dialkyl siloxane.

8. The method of claim 4, wherein the upper protective layer is formed of ethylene vinyl acetate (EVA) of a film form.
